(19) United States
(12) Patent Application Publication
(10) Pub. No.: US 2025/0113651 A1
(43) Pub. Date: Apr. 3, 2025

(54) NANOBUBBLES FOR FABRICATION OF POROUS THIN FILMS

(71) Applicant: Moleaer, Inc., Hawthorne, CA (US)

(72) Inventors: Mohamed E. Abdelrahman, Irvine, CA (US); Sohail Akhter, Carson, CA (US)

(21) Appl. No.: 18/899,276

(22) Filed: Sep. 27, 2024

Related U.S. Application Data
(60) Provisional application No. 63/586,273, filed on Sep. 28, 2023.
(60) Provisional application No. 63/610,200, filed on Dec. 14, 2023.
(60) Provisional application No. 63/675,411, filed on Jul. 25, 2024.

(51) Int. Cl. H01L 31/0224; H01L 31/18; H10K 71/15; H10K 71/60

(52) U.S. Cl. CPC H10F 77/211; H10F 71/00; H10K 71/15; H10K 71/60

(57) ABSTRACT

Provided herein are methods that involve the use of nanobubbles for fabrication of porous thin films that can be used to form articles such as electrodes, membranes, and photovoltaic cells. One such method includes combining nanobubbles with catalyst nanoparticles, a liquid carrier, and an ionomer to form a coating composition; applying the coating composition to a substrate to form a coated substrate; and removing the liquid carrier from the coated substrate to form an electrode including a porous thin film on the substrate.

### CLAIM OF PRIORITY

This application claims priority to U.S. Provisional Application Ser. No. 63/586,273, filed on Sep. 28, 2023, U.S. Provisional Application Ser. No. 63/610,200, filed on Dec. 14, 2023, and U.S. Provisional Application Ser. No. 63/675,411, filed on Jul. 25, 2024, the contents of which are hereby incorporated by reference.

### TECHNICAL FIELD

This disclosure relates to fabrication of porous thin films.

### BACKGROUND

Porous thin films include a wide range of materials that are often characterized by their porosity, which can include characterization of pore size and/or number of pores. Porous thin films can be used in a wide range of applications including catalysis, filtration, signal detection, energy conversion, and light transmission.

### SUMMARY

The inventors have discovered that the porous thin films can be fabricated using coating compositions including nanobubbles. Such porous thin films exhibit improved performance as compared to conventionally fabricated thin films. For instance, thin films fabricated using nanobubble-containing catalyst ink for use in electrodes have improved performance, such as improved charge transport, mass transport, catalytic utilization, and/or cell resistance.

Accordingly, aspects of the present disclosure provide a method of preparing an article comprising: a) combining nanobubbles with a film-forming agent to form a coating composition; b) applying the coating composition to a substrate to form an article comprising a porous thin film on the substrate.

In some embodiments, the film-forming agent comprises a metal, a polymer, a ceramic, or a combination thereof. The polymer can include an ionomer. In some embodiments, the film-forming agent comprises a photoactive material, and wherein the porous thin film comprises a photoactive layer. The photoactive material can comprise an organic material, an organometallic material, a metal oxide, a perovskite, a quantum dot, a chalcogenide, or a combination of any of these. In some embodiments, wherein the film-forming agent comprises a semiconducting material. In some embodiments, the porous thin film comprises a semiconducting layer. The liquid carrier can include water or an organic solvent.

In some embodiments, the method includes applying a semiconductor coating composition to the substrate to form a semiconducting layer on the substrate, the semiconductor coating composition comprising nanobubbles, a semiconducting material, and a liquid carrier. In some embodiments, applying the coating composition to the substrate comprises applying the coating composition to the semiconducting layer to form the photoactive layer on the semiconducting layer. In some embodiments, the substrate comprises a first electrode, and the method comprises disposing a second electrode onto the photovoltaic layer to form a photovoltaic cell. In some embodiments, applying the coating composition to a substrate comprises applying the coating composition to an electrode. In some embodiments, applying the coating composition to a substrate comprises applying the coating composition to an electrode.

In some embodiments, the method includes combining nanobubbles, the film-forming agent, and a liquid carrier to form the coating composition. In some embodiments, applying the coating composition to the substrate comprises removing the liquid carrier from the coated substrate to form the article comprising the porous thin film.

The coating composition includes nanobubbles, catalyst nanoparticles, and the film-forming agent in certain embodiments. The catalyst nanoparticles can include iridium oxide nanoparticles. The catalyst nanoparticles and film-forming agent can be present in an amount ranging from 0.1-80 wt. % based on the weight of the coating composition. In some embodiments, the coating composition comprises nanobubbles, catalyst nanoparticles, a liquid carrier, and the film-forming agent. In some embodiments, the film-forming agent comprises an ionomer. In some embodiments, the article comprises an electrode. In some embodiments, the electrode is a cathode or an anode of a battery (e.g., Li-ion battery, solid-state battery, etc.). In some embodiments, the cathode for a lithium ion battery may include lithium cobalt oxide (LiCO₂), lithium nickel manganese cobalt oxide (NMC), lithium nickel cobalt aluminum oxide (NCA), lithium manganese oxide (LMO), lithium iron phosphate (LFP), lithium-rich NMC, lithium titanate (LTO), or a combination thereof. In some embodiments, the anode for the lithium ion battery may include graphite, silicon-based materials, lithium titanate (Li₄Ti₅O₁₂), hard carbon, soft carbon, or combinations thereof. In some embodiments, the cathode for a solid-state battery includes lithium nickel manganese cobalt oxide (NMC), lithium iron phosphate (LFP), lithium sulfur (Li—S), lithium metal oxides, a sulfur cathode, lithium transition metal phosphates, or a combination thereof. In some embodiments, the anode for a solid-state battery includes lithium metal, graphite, silicon-based materials, composite anodes, or a combination thereof.

The coating composition can include nanobubbles having a mean bubble size no greater than 1000 nm, e.g., no greater than 750 nm, no greater than 500 nm, or no greater than 250 nm.

The porous thin film can include pores having an average pore size between 50 and 1000 nm, e.g., between 250 and 1000 nm, between 500 and 1000 nm, between 750 and 1000 nm, between 50 and 750 nm, between 50 and 500 nm, or between 50 and 250 nm. In various embodiments, the porous thin film can include pores having an average pore size between 100 and 200 nm, e.g., between 115 and 135 nm.

In various embodiments, the article includes an electrode. The article can include a filtration membrane, an ion-conduction membrane, a battery separator, an electrolyzer diaphragm, a semi-conductor layer in a photovoltaic cell, or any functional layer used in electrochemical, solar, photo-electrochemical, or filtration applications.

Aspects of the present disclosure provide an article that can be prepared according to any one of the methods described herein. For example, in certain implementations, the present disclosure provides a method of preparing an electrode comprising a) combining nanobubbles with catalyst nanoparticles, a liquid carrier, and a polymer to form a coating composition; b) applying the coating composition to a substrate to form a coated substrate; and c) removing the liquid carrier from the coated substrate to form an electrode comprising a porous thin film on the substrate. In some embodiments, the polymer comprises an ionomer.

The liquid carrier can include water, an organic solvent, or both water and an organic solvent.

The catalyst nanoparticles can include iridium oxide nanoparticles. The catalyst nanoparticles and ionomer can be present in an amount ranging from 0.1-80 wt. % based on the weight of the coating composition.

The coating composition can include nanobubbles having a mean bubble size no greater than 1000 nm, e.g., no greater than 750 nm, no greater than 500 nm, or no greater than 250 nm.

The porous thin film can include pores having an average pore size between 50 and 1000 nm, e.g., between 250 and 1000 nm, between 500 and 1000 nm, between 750 and 1000 nm, between 50 and 750 nm, between 50 and 500 nm, or between 50 and 250 nm. In various embodiments, the porous thin film can include pores having an average pore size between 100 and 200 nm, e.g., between 115 and 135 nm.

In certain implementations, methods described herein include positioning the electrode between an anode porous transport layer and a cathode gas diffusion layer to form a membrane electrode assembly.

Aspects of the present disclosure provide an electrode that can be prepared according to any one of the methods described herein.

In certain implementations, the present disclosure provide a nanobubble-containing catalyst ink composition that includes catalyst nanoparticles, an ionomer, and nanobubbles.

Aspects of the present disclosure provide a method of preparing an article comprising a) combining nanobubbles and a film-forming agent to form a coating composition; and b) applying the coating composition to a substrate to form an article comprising a porous thin film on the substrate.

In some embodiments, the film-forming agent comprises a metal, a polymer, or a combination thereof. In some embodiments, the polymer comprises an ionomer. In some embodiments, the film-forming agent comprises a photoactive material. In some embodiments, the photoactive material comprises an organic material, an organometallic material, a metal oxide, a perovskite, a quantum dot, a chalcogenide, or a combination of any of these. In some embodiments, the film-forming agent comprises a semiconducting material.

In some embodiments, the coating composition comprises nanobubbles having a mean bubble size no greater than 250 nm.

Aspects of the present disclosure provide a method of preparing a photovoltaic cell comprising a) combining nanobubbles with a photoactive material and a liquid carrier to form a coating composition; and b) applying the coating composition to a substrate to form a photovoltaic layer on the substrate.

In some embodiments, the liquid carrier comprises water or an organic solvent.

In some embodiments, the photoactive material comprises an organic material, an organometallic material, a metal oxide, a perovskite, a quantum dot, a chalcogenide, or a combination of any of these.

In some embodiments, the coating composition comprises nanobubbles having a mean bubble size no greater than 250 nm.

In some embodiments, the substrate comprises a first electrode, and comprising disposing a second electrode onto the photovoltaic layer to form a photovoltaic cell.

In some embodiments, the method comprises applying a semiconductor coating composition to the substrate to form a semiconducting layer on the substrate, the semiconductor coating composition comprising nanobubbles, a semiconducting material, and a liquid carrier; and wherein applying the coating composition to the substrate to form a photovoltaic layer on the substrate comprises applying the coating composition to the semiconducting layer.

In some embodiments, the method comprises applying a semiconductor coating composition to the photovoltaic layer to form a semiconducting layer on the photovoltaic layer, the semiconductor coating composition comprising nanobubbles, a semiconducting material, and a liquid carrier.

Aspects of the present disclosure provide a photovoltaic cell that can be prepared according to any one of the methods described herein. For example, in certain implementations, the present disclosure provides a method of preparing a photovoltaic cell comprising a) combining nanobubbles with a semiconducting material and a liquid carrier to form a coating composition; and b) applying the coating composition to a substrate to form a semiconducting layer on the substrate.

In some embodiments, applying the coating composition to a substrate comprises applying the coating composition to an electrode. In some embodiments, applying the coating composition to a substrate comprises applying the coating composition to a photovoltaic layer.

Other features and advantages of the disclosure will be apparent from the following detailed description, and from the claims.

### BRIEF DESCRIPTION OF DRAWINGS

FIG. 1 shows a schematic depiction of an example catalyst ink formulation process involving an iridium oxide proton exchange membrane water electrolyzer (PEMWE) anode catalyst ink.

FIG. 2 shows a schematic depiction of an example electrode coating and membrane electrode assembly (MEA) fabrication process.

FIG. 3 shows graphs of polarization curves of a MEA prepared using nanobubble-containing catalyst ink (NB CL) and a control MEA prepared with catalyst ink free of nanobubbles (Typical CL). Potentiostatic IV curves were normalized to geometric active area (left) or total mass of an anode iridium oxide catalyst (right).

FIG. 4A shows a graph of a cyclic voltammetry (CV) curve of an anode in a PEMWE. FIG. 4B shows a plot of a polarization curve of a MEA prepared using nanobubble-containing catalyst ink and a control MEA prepared using catalyst ink free of nanobubbles. Untreated CL: catalyst layer prepared using catalyst ink free of nanobubbles; NB-treated CL: catalyst layer prepared using nanobubble-containing catalyst ink.

FIGS. 5A-5B show graphs of electrochemical impedance spectroscopy (EIS) data of a PEMWE anode at 1.5 V. FIG. 5A shows a Nyquist plot with markers showing experimental data and lines showing DRT fits. FIG. 5B shows a DRT spectra attained from fitting experimental datasets. Untreated CL: catalyst layer prepared using catalyst ink free of nanobubbles; NB-treated CL: catalyst layer prepared using nanobubble-containing catalyst ink.

FIG. 6 shows a graph of pore size distribution of the catalyst layer prepared using nanobubble-containing catalyst ink (NB-treated CL) and the control catalyst layer prepared using catalyst ink free of nanobubbles (Untreated CL) generated by analyzing a 3D image dataset acquired from focused ion beam-scanning electron microscopy (FIB-SEM).

FIG. 7 shows the renderings of the control catalyst layer prepared using catalyst ink free of nanobubbles (baseline CL) and the catalyst layer prepared using nanobubble-containing catalyst ink (NB-treated CL) and a summary of structural properties of the NB-treated CL and the baseline CL generated by analyzing a 3D image dataset.

FIGS. 8A-8B show electrochemical impedance spectroscopy (EIS) at different relative humidities and using the fluorinated inert fluid (FC40). FIG. 8A shows the EIS at different relative humidities using the fluorinated inert fluid (FC40) for the baseline CL. FIG. 8B shows the EIS at different relative humidities using the fluorinated inert fluid (FC40) for the NB-treated CL.

FIG. 9 shows calculated ionomer coverage values for the baseline CL and the NB-treated CL

### DETAILED DESCRIPTION

The methods described herein are directed to using nanobubbles for fabrication of porous thin films (e.g., porous thin films for electrodes, porous thin films membranes, porous thin films for photovoltaic cells). Generally, thin films are formed from coating compositions including nanobubbles, among other components. For instance, for fabrication of porous thin films for use in electrodes, the coating compositions include catalyst nanoparticles and a film-forming agent such as an ionomer. In another instance, for fabrication of porous thin films for use in photovoltaic cells, the coating compositions include a photoactive or semiconducting material. The nanobubble size and concentration in the coating composition, such as a catalyst ink, can be selected to tune the porosity of the resulting film.

Forming porous thin films (e.g., catalyst layers) from coating compositions (e.g., catalyst inks) including nanobubbles provides several improvements over conventional porous thin films. Such improvements include, but are not limited to:
(a) Increased surface area of the porous thin film resulting at least in part from increased porosity due to the formation of a large number of small pores.
(b) Increased catalytic utilization of porous thin films made using nanobubble-containing coating compositions compared to conventional porous thin films resulting at least in part from increased electrochemical active surface area (ESCA).
(c) Improved charge transfer, ion transport, and/or mass transport of porous thin films made using nanobubble-containing coating compositions compared to conventional porous thin films resulting at least in part from more even and regular ionomer distribution or distribution of photoactive or semiconducting material in nanobubble-containing coating compositions compared to ionomer distribution or distribution of photoactive or semiconducting material in nanobubble-free coating compositions.
(d) Improved the mass transport of reactants and products through the porous thin films as compared to conventional porous thin films. For example, when the porous thin film is a catalyst layer, this improves product purging out of the catalyst layer and reactant availability within the catalyst layer especially at high current densities.
(e) Improved durability of the porous thin films made using nanobubble-containing coating compositions compared to conventional porous thin films.

These advantages are relevant, for instance, when nanobubbles are used to fabricate electrodes for electrochemical conversion devices such as electrolyzers and fuel cells. Electrolyzers are devices that are used for electrochemical water splitting to produce hydrogen and oxygen gases using a direct current (DC) power supply, e.g., from a renewable energy source. Fuel cells convert stored potential energy in fuels such as hydrogen into electricity. The performance of electrodes in both of these instances, when the electrodes are fabricated using nanobubbles, is enhanced due to increased ESCA, improved (e.g., more even and regular) distribution of ionomer, and/or improved mass transport properties. For instance, when electrodes that include catalyst layers are implemented in electrolyzers, this increased ESCA leads to improved efficiency and performance of the electrolyzer for a given catalyst loading, or alternatively, the ability to achieve a similar performance at a lower catalyst loading as compared to otherwise similar catalyst layers fabricated without nanobubbles.

These advantages are also relevant, for instance, when nanobubbles are used in the context of solution-based processing of photovoltaic materials to form photoactive layers for photovoltaic cells (also referred to as solar cells). Similar advantages are also applicable to semiconducting layers, e.g., electron or hole transport layers, that are disposed adjacent to of the photoactive layer of a photovoltaic cell. A photoactive layer of a photovoltaic cell converts light into an electrical current. The adjacent semiconducting layers facilitate transport of charge (e.g., electrons and holes) to and from the photoactive layer. The performance of photoactive and semiconducting layers, when fabricated using nanobubbles, is enhanced due to increased ESCA, improved (e.g., more even and regular) distribution of photoactive and semiconducting material, and/or improved mass transport properties. For instance, when porous thin film photoactive and/or semiconducting layers are implemented in photovoltaic cells, this increased ESCA leads to improved efficiency and performance of the photovoltaic cells compared to porous thin films fabricated without nanobubbles. Additionally, fabricating photoactive and/or semiconducting layers using nanobubbles can enable formation of a rough, porous structure at the p-n junction interface of the photovoltaic cell, which provides a high surface area for charge exchange and shorter paths for electron and hole transport, thus improving conversion efficiency. Furthermore, the incorporation of nanobubbles into solution-based processing of photovoltaic materials can facilitate dispersion of active particles in the solution prior to deposition, which in turn can contribute to improved performance, e.g., higher yield.

A porous thin film refers to a film having a plurality of pores. In some embodiments, the porous thin film can include a plurality of pores having an average pore size of between 10 and 1000 nm. A catalyst layer (CL) refers to a layer of material made from a substrate (e.g., membrane) that includes catalyst nanoparticles dispersed on the substrate. A photoactive layer refers to a layer of material that includes a photoactive material. A semiconducting layer refers to a layer of material that includes a semiconducting material.

Following below are more detailed descriptions of various concepts related to, and exemplary embodiments of, inventive methods related to using nanobubbles for fabrication of porous thin films (e.g., catalyst layers), such as porous thin films having a thickness of less than about 5000 nm, such as between 10 nm and 1000 um. Improved performance of porous thin films, such as catalyst layers for electrodes or photovoltaic layers or semiconducting layers for photovoltaic cells, prepared as described herein can include one or more of the following: improved charge transport, improved mass transport, improved catalytic utilization, and improved cell resistance.

### Preparation of Nanobubble-Containing Coating Compositions

Methods described herein comprise preparing nanobubble-containing coating compositions (e.g., nanobubble-containing catalyst inks). As used herein, the term “nanobubble” refers to a bubble that has a diameter of less than one micron.

In some embodiments, methods described herein comprise combining nanobubbles with a film-forming agent to form a coating composition. In some embodiments, methods described herein comprise combining nanobubbles with a liquid carrier and a film-forming agent to form a coating composition. In some embodiments, methods described herein comprise combining nanobubbles with a liquid carrier, catalyst nanoparticles, and an ionomer to form a coating composition. In such instances, the coating composition can be a catalyst ink. The presence of nanobubbles in the coating composition introduces small gas bubbles, e.g., with average diameter of less than 250 nm, into the composition. The bubbles are dispersed throughout the coating composition, providing benefits to the structure and performance of the resulting film.

Any liquid carrier suitable for forming a coating composition (e.g., a catalyst ink) can be used in methods described herein. In some embodiments, the liquid carrier comprises water, an organic solvent, or a combination of any of these. Non-limiting examples of organic solvents for use in a liquid carrier described herein include acetone, ethylene glycol, ethylene glycol diethyl ether (EGDEE), ethylene glycol dimethyl ether (EGDME), glycerin, propylene glycols, or a combination of any of these. Other examples of organic solvents for use in a liquid carrier described herein include alcohols including, but not limited to, 1-butanol, 1-propanol, 2-butanol, 2-propanol, ethanol, isobutyl alcohol, methanol, pentanol, tert-butyl alcohol, or a combination of any of these.

Any film-forming agent suitable for forming a coating composition can be used in methods described herein. Non-limiting examples of film-forming agents for use in the coating compositions described herein include metals (e.g., nickel, niobium, tantalum, titanium, tin, zinc, zirconium, or a combination of any of these, or metal oxides of any one or a combination of these (e.g., titanium oxide, tin oxide, nickel oxide, zinc oxide, or a combination of any of these); redox polymers (e.g., poly(vinylferrocene)); ion-exchange polymers (e.g., ionomers such as perfluorosulfonate ionomers); electronically conductive polymers (e.g., polyaniline, polypyrrole, polythiophene, or a combination of any of these); a ceramic, or a combination of any of these.

In some embodiments, the film-forming agent includes a photoactive material, such as an organic or a metalloorganic material. Non-limiting examples of photoactive materials include metals (e.g., lead, nickel, niobium, tantalum, titanium, tin, zinc, zirconium, or a combination of any of these, or metal oxides of any one or a combination of these (e.g., titanium oxide, tin oxide, nickel oxide, zinc oxide, or a combination of any of these); polymers (e.g., polystyrene, polypropylene); conjugated polymers (e.g., poly(3-hexylthiophene) (P3HT), poly[N-9′-heptadecanyl-2,7-carbazole-alt-5,5-(4′,7′-di-2-thienyl-2′,1′,3′-benzothiadiazole)] (PCDTBT), poly[2,6-(4,4-bis(2-ethylhexyl)-4H-cyclopenta[2,1-b;3,4-b′]dithiophene)-alt-4,7(2,1,3-benzothiadiazole)] (PCPDTBT), or a combination of any of these); quantum dots (e.g., lead sulfide (PbS) quantum dots, lead selenide (PbSe) quantum dots, cadmium selenide (CdSe) quantum dots, cadmium telluride (CdTe) quantum dots, copper indium sulfide (CuInS₂) quantum dots, zinc oxide (ZnO) quantum dots, silicon quantum dots, or a combination of any of these); chalcogenides (e.g., copper indium gallium selenide (CIGS), copper zinc tin sulfide (CZTS), or a combination thereof); perovskites (e.g., methylammonium lead halides such as methylammonium lead iodide (MAPbI₃), formamidinium lead iodide (FAPbI₃), cesium lead iodide (CsPbI₃), mixed halide perovskites (MAPb(I,Br)₃), double perovskites (Cs₂AgBiBr₆), small molecules (e.g., pentacene, perylene diimides, phthalocyanines (e.g., copper phthalocyanine, squaraines, or a combination of any of these); fullerenes or fullerene derivatives (e.g., [6,6]-phenyl-C₆₁-butyric acid methyl ester (PCBM), [6,6]-phenyl-C₇₁-butyric acid methyl ester (PC₇₁BM), or a combination thereof); dyes (e.g., ruthenium complex dyes (e.g., N719, N3), zinc porphyrin dyes (e.g., YD2-o-C8), metal-free organic dyes (e.g., D5, D35), or a combination of any of these); or hybrid materials such as hybrid perovskites (e.g., hybrid perovskites including methylammonium lead iodine and a polymer, a quantum dot, or both) or hybrid materials for dye-sensitized solar cells (e.g., titania nanoparticles with ruthenium or organic dyes).

In some embodiments, the film-forming agent includes a semiconducting material, such as a p-type or n-type semiconductor, e.g., p-type or n-type silicon or other suitable semiconductor.

In some embodiments, the film-forming agent comprises an ionomer. Any ionomer suitable for forming a coating composition can be used in methods described herein. In some embodiments, the ionomer can comprise a partially fluorinated polymer or a fully fluorinated polymer. In some embodiments, the ionomer comprises one or more functional groups selected from a bis-carbonyl imide, a bis-sulfonyl imide, a carboxylic acid, a phosphonic acid, a sulfonic acid, a sulfonyl amide, a sulfonyl carbonyl imide, and a combination of any of these. In some embodiments, the ionomer comprises a copolymer of perfluoro-3,6-dioxa-4-methyl-7octene-sulfonic acid and tetrafluoroethylene.

In some embodiments, the ionomer comprises a non-fluorinated polymer. Non-limiting examples of non-fluorinated ionomers for use in coating compositions described herein include polymers comprising polybenzimidazole/phosphoric acid, sulfonated polyarylethersulfone, sulfonated polyetheretherketone, sulfonated polyetherimide, sulfonated polyethersulfone, sulfonated poly(phenoxyphosphazene), and a combination of any of these.

Non-limiting examples of ionomers for use in coating compositions described herein include Nafion™ polymers (a copolymer of perfluoro-3,6-dioxa-4-methyl-7octene-sulfonic acid and tetrafluoroethylene from The Chemours Company, Wilmington, DE), 3M™ ionomers (copolymers of tetrafluoroethylene and perfluorobutanesulfonylfluoride vinyl ether from 3M Company, Saint Paul, MN), Aquivion® ionomers (chemically-stabilized, short side chain (SSC) perfluorosulfonic acid ionomer from Solvay, Brussels, Belgium), and a combination of any of these.

In some embodiments, the coating composition, e.g., a catalyst ink, can include catalyst nanoparticles. Any catalyst nanoparticles suitable for forming a porous thin film, such as a catalyst layer, can be used in methods described herein. In some embodiments, the catalyst nanoparticles comprise metal nanoparticles, e.g., aluminum nanoparticles, barium nanoparticles, bismuth nanoparticles, chromium nanoparticles, cobalt nanoparticles, copper nanoparticles, gold nanoparticles, iridium nanoparticles, iron indium nanoparticles, lead nanoparticles, nickel nanoparticles, osmium nanoparticles, palladium nanoparticles, platinum nanoparticles, rhodium nanoparticles, ruthenium nanoparticles, silver nanoparticles, tantalum nanoparticles, tin nanoparticles, titanium nanoparticles, tungsten nanoparticles, zinc nanoparticles, or a combination of any of these (e.g., titanium nanoparticles including ruthenium), or metal oxides nanoparticles of any one or a combination of these. In some embodiments, the catalyst nanoparticles include a dye (e.g., titanium nanoparticles including ruthenium and a dye).

In some embodiments, the catalyst nanoparticles comprise platinum group transition metal nanoparticles, e.g., iridium nanoparticles, osmium nanoparticles, palladium nanoparticles, platinum nanoparticles, rhodium nanoparticles, ruthenium nanoparticles, or a combination of any of these. In some embodiments, the catalyst nanoparticles comprise platinum group transition metal oxide nanoparticles, e.g., iridium oxide nanoparticles, osmium oxide nanoparticles, palladium oxide nanoparticles, platinum oxide nanoparticles, rhodium oxide nanoparticles, ruthenium oxide nanoparticles, or a combination of any of these, or metal oxides of any one or a combination of these.

In some embodiments, methods described herein comprise combining nanobubbles with catalyst nanoparticles (e.g., iridium oxide nanoparticles), an ionomer (e.g., sulfonated tetrafluoroethylene based fluoropolymer-copolymer), and a liquid carrier (e.g., 2-propanol and water), to form porous thin films (e.g., catalyst layers) for use in electrodes.

In some embodiments, the coating composition includes solids (e.g., combination of catalyst nanoparticles and film-forming agent, such as ionomer) in a total amount of about 0.1 wt. % to about 80 wt. % of the coating composition (weight of the catalyst nanoparticles and the film-forming agent/weight of the coating composition), e.g., about 0.5 wt. % to about 80 wt. %, about 1 wt. % to about 80 wt. %, about 5 wt. % to about 80 wt. %, about 10 wt. % to about 80 wt. %, about 15 wt. % to about 80 wt. %, about 20 wt. % to about 80 wt. %, about 25 wt. % to about 80 wt. %, about 30 wt. % to about 80 wt. %, about 40 wt. % to about 80 wt. %, about 50 wt. % to about 80 wt. %, about 60 wt. % to about 80 wt. %, about 70 wt. % to about 80 wt. %, about 0.1 wt. % to about 70 wt. %, about 0.1 wt % to about 60 wt. %, about 0.1 wt. % to about 50 wt. %, about 0.1 wt. % to about 40 wt. %, about 0.1 wt % to about 35 wt. %, about 0.1 wt. % to about 30 wt. %, about 0.1 wt. % to about 25 wt. %, about 0.1 wt. % to about 20 wt. %, about 0.1 wt. % to about 15 wt. %, about 0.1 wt. % to about 10 wt. %, about 0.1 wt. % to about 5 wt. %, about 0.1 wt. % to about 1 wt. %, or about 0.1 wt. % to 0.5 wt. % of the coating composition (weight of the catalyst nanoparticles and the film-forming agent/weight of the coating composition).

For instance, the coating composition, such as a catalyst ink, includes an ionomer and catalyst nanoparticles in a ratio of 0.05:1 to 0.5:1 (ionomer:catalyst nanoparticles), e.g., 0.05:1, 0.1:1, 0.15:1, 0.2:1, 0.3:1, 0.4:1, or 0.5:1 (ionomer:catalyst nanoparticles).

In some embodiments, the coating composition includes nanobubbles at a concentration of at least 10⁶ nanobubbles per mL, at least 10⁷ nanobubbles per mL, at least 10⁸ nanobubbles per mL, at least 10⁹ nanobubbles per mL, at least 10¹⁰ nanobubbles per mL, at least 10¹¹ nanobubbles per mL, or more. For instance, the concentration of nanobubbles can be at saturation in the coating composition.

In some embodiments, the coating composition includes nanobubbles having a mean bubble size of no greater than 1000 nm, e.g., no greater than 750 nm, no greater than 500 nm, or no greater than 250 nm. For instance, the nanobubbles in the coating composition can have a mean bubble size of between 120 and 140 nm, e.g., between 125 and 140 nm, between 130 and 140 nm, between 135 and 140 nm, between 120 and 135 nm, or between 120 and 130 nm.

Nanobubbles for use in methods described herein can include any gas. Non-limiting examples of gases include air, hydrogen, biogas, methane, carbon dioxide, nitrogen, oxygen, or ozone.

Methods described herein encompass generating nanobubbles in a coating composition (e.g., a catalyst ink) or combining nanobubbles with the coating composition. In some embodiments, methods include combining nanobubbles (e.g., nanobubbles in solvent) with one or more of the following: a liquid carrier, a film-forming agent, catalyst nanoparticles, an ionomer, or a combination thereof.

In some examples, nanobubbles are generated or introduced into a solution during the process of preparing the solution, e.g., when mixing the constituents of the composition, to form a nanobubble-containing coating composition. In some examples, the solution is prepared, and nanobubbles are introduced into the solution to form a coating composition just before application to a substrate.

Any method known in the art or described herein can be used to generate nanobubbles for use in methods described herein. Non-limiting examples of methods and apparatuses for generating nanobubbles that can be used in methods described herein are provided in U.S. Pat. Nos. 10,591,231, and 11,331,633, the entire contents of which are herein incorporated by reference for the purposes and subject matter referenced herein.

### Preparation of Porous Thin Films

Methods described herein can include applying any of the nanobubble-containing coating compositions (e.g., nanobubble-containing catalyst inks) described herein to a substrate to form a coated substrate. In some examples, the application of a nanobubble-containing coating composition to a substrate forms an article having a porous thin film on the substrate. In some examples, when the nanobubble-containing coating composition includes a liquid carrier, the methods include removing the liquid carrier from the coated substrate after application of the nanobubble-containing coating substrate to the substrate to thereby form a porous thin film (e.g., a catalyst layer) on the substrate. Accordingly, in some embodiments, a coated substrate can refer to a substrate with the coating composition applied thereon.

Any substrate known in the art or described herein can be used in methods described herein. Non-limiting examples of a substrate include an electrode, a membrane (e.g., a filtration membrane), a metal-based substrate (e.g., aluminum, copper, titanium, stainless-steel), a carbon-based substrate (e.g., carbon cloth, carbon nanofibers, carbon nanotubes, graphene), an inorganic-based substrate (e.g., glass), a polymer-based substrate (e.g., polytetrafluoroethylene), or a combination of any of these.

A substrate for use in methods described herein can be any shape or form suitable for forming a porous thin film on the substrate. For example, the metal-based substrate can include metal foam, metal foil, metal mesh, metal wire, or a combination of any of these.

Methods described herein encompass use of any method known in the art or described herein to apply a coating composition, such as a catalyst ink, to a substrate. Non-limiting examples of methods of applying a coating composition to a substrate include roll-to-roll, doctor blading, brush painting, spray coating, spin coating, inkjet coating, or a combination of any of these.

Any of the methods described herein can also include removing the liquid carrier from the coated substrate to form a porous thin film, such as a catalyst layer, on the substrate. In some embodiments, methods described herein include removing the liquid carrier from the coated substrate to form an electrode including a porous thin film on the substrate.

Any method known in the art or described herein can be used in methods described herein to remove a liquid carrier from a substrate to form a porous thin film, such as a catalyst layer, on the substrate. In some embodiments, removing the liquid carrier includes drying the coating composition on the substrate, e.g., by heating the substrate to remove the liquid carrier. In some embodiments, removing the liquid carrier includes heating the substrate for a sufficient time and at a sufficient temperature to remove the liquid carrier from the substrate to form a porous thin film on the substrate. In some embodiments, removing the liquid carrier can include heating the substrate on a hot plate at a temperature between 60° C. and 80° C., e.g., 70° C.

Any method known in the art or described herein can be used in methods described herein to form a porous thin film, such as a catalyst layer, on a substrate include solvent casting, spin casting, sol-gel processes, or a combination of any of these.

Methods described herein can be used to prepare a porous thin film including pores having any desired pore size. In some embodiments, the porous thin film includes pores having an average pore size between 10 and 1000 nm, e.g., between 100 and 1000 nm, between 250 and 1000 nm, between 500 and 1000 nm, between 750 and 1000 nm, between 10 and 750 nm, between 10 and 500 nm, between 10 and 250 nm, or between 10 and 100 nm.

In some embodiments, the porous thin film includes pores having an average pore size between 115 and 135 nm, e.g., between 120 and 135 nm, between 125 and 135 nm, between 130 and 135 nm, between 115 and 130 nm, between 115 and 125 nm, or between 115 and 120 nm. In some embodiments, the porous thin film includes pores having an average pore size of 115 nm, 120 nm, 125 nm, or 130 nm.

Methods described herein can be used to prepare a porous thin film having any desired porosity. In some embodiments, the porous thin film includes a porosity between 20 and 40%. In some embodiments, the porous thin film includes a porosity of 20%, 21%, 22%, 23%, 24%, 25%, 26%, 27%, 28%, 29%, 30%, 31%, 32%, 33%, 34%, 35%, 36%, 37%, 38%, 39%, 40%, or more.

Methods described herein encompass transferring the porous thin film from one substrate to another substrate. Any method known in the art or described herein can be used to transfer a porous thin film in methods described herein. For example, methods described herein can include transferring a porous thin film from a substrate to a membrane to form a catalyst coated membrane using a hot press.

Methods described herein encompass combining a substrate including a porous thin film with one or more additional layers to form an assembly. For example, methods described herein can include positioning the porous thin film on the substrate between an anode porous transport layer, an ionomer membrane, a cathode electrode, and a cathode gas diffusion layer to form a membrane electrode assembly.

Methods described herein encompass combining a substrate including a porous thin film with one or more additional layers to form a photovoltaic cell. For example, methods described herein can include forming a porous thin film photovoltaic layer on a substrate. Specifically, the porous thin film photovoltaic layer can be disposed on the substrate between a positive electrode and a negative electrode to form a photovoltaic cell, or between a p-type and an n-type semiconducting layer. In some examples, the methods described herein can including forming one or both of the p-type and the n-type semiconducting layer using nanobubbles, e.g., in addition to or instead of forming the photovoltaic layer using nanobubbles.

Non-limiting examples of photovoltaic cells that can include a porous thin film prepared according to any one of the methods described herein include photovoltaic cells that incorporate solution processable photovoltaic materials, such as organic photovoltaic cells, perovskite photovoltaic cells, dye-sensitized photovoltaic cells, quantum dot photovoltaic cells, hybrid photovoltaic cells, and thin-film photovoltaic cells. Preparation of organic photovoltaic cells using nanobubbles involves dissolving organic semiconductors in a solvent, adding nanobubbles into the solution containing organic semiconductors to form a coating composition, and applying the coating composition onto a substrate, e.g., by spin coating, printing, doctor blading, or other approaches. Preparation of other types of photovoltaic cells can follow a generally similar process, e.g., in which a coating composition containing a photoactive material and nanobubbles is applied onto a substrate as part of forming a photovoltaic cell.

The present disclosure also provides a substrate including a porous thin film prepared according to any one of the methods described herein. Also provided herein is an electrode including a porous thin film prepared according to any one of the methods described herein. Also provided herein is a photovoltaic cell including a porous thin film photovoltaic layer and/or one or more semiconducting layers prepared according to any one of the methods described herein. Substrates, electrodes, and photovoltaic cells prepared according to methods described herein can be used in any method known in the art or described herein.

### EXAMPLES

The following examples described in this application are offered to illustrate the methods provided herein and are not to be construed in any way as limiting.

### Example 1: Fabrication of Electrodes Using Nanobubble-Containing Catalyst Ink

This Example describes the process of introducing nanobubbles into a catalyst ink and coating the electrode with the catalyst ink. Nanobubbles with diameters in the 100 nm range were introduced into the majority of the solvent used to formulate a proton exchange membrane water electrolyzer (PEMWE) catalyst ink.

The catalyst ink included a mixture of catalyst (iridium oxide nanoparticles), n-propanol (NPA), deionized (DI) water, ionomer (perfluorosulfonic acid (PFSA) solution, which is a colloidal mixture of solid PFSA, NPA, DI water, and ethanol). The solids content (e.g., catalyst, ionomer, or both) of the catalyst ink was from about 1 wt % to about 10 wt % (weight of solids/volume of catalyst ink). The water content of the catalyst ink was from about 15 wt % to about 75 wt % (volume of water/volume of catalyst ink).

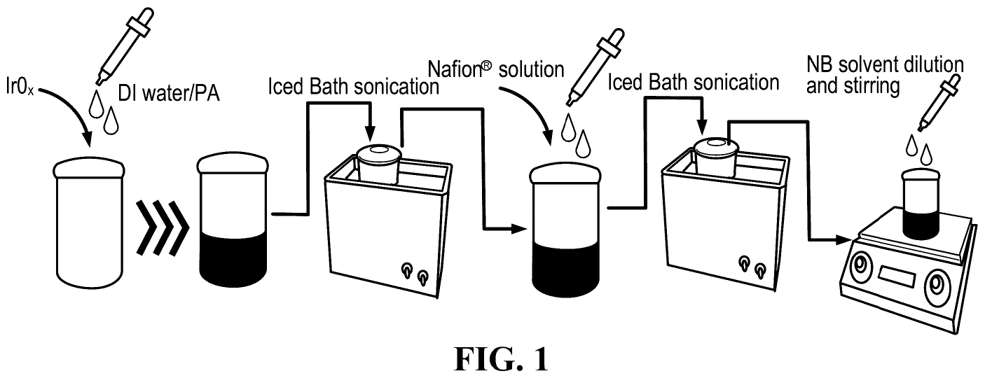

FIG. 1 shows a schematic depiction of an example catalyst ink formulation process for an iridium oxide PEMWE anode catalyst ink. As shown in FIG. 1, solvent, catalyst, and ionomer solution were added to a vial, and the vial was sonicated. The nanobubble-containing solvent was then added to dilute the sonicated catalyst ink, and the resulting mixture was stirred.

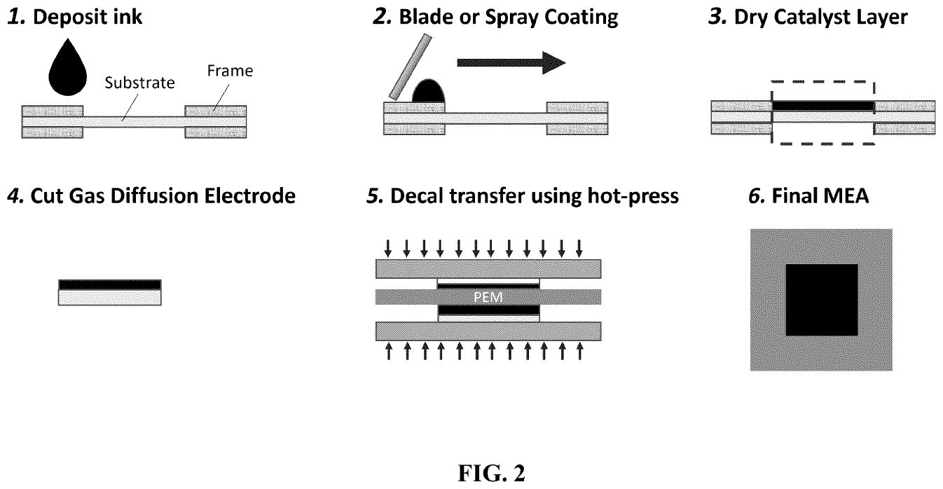

FIG. 2 shows a schematic depiction of an example electrode coating and membrane electrode assembly (MEA) fabrication process. As shown in FIG. 2, after sufficient stirring of the mixture of nanobubble-containing solvent and sonicated catalyst ink, a frame with a specified area of polytetrafluoroethylene (PTFE) as the polymer substrate exposed for coating the catalyst ink was prepared. The ink was coated using a doctor blade coating technique with a hot plate set to 70° C., the electrode was allowed to dry, and then it was cut. The anode and cathode decals were aligned onto an ionomer membrane and placed into a hot press for decal transfer. Following transfer, the substrate was peeled off, which resulted in a catalyst coated membrane (CCM). The CCM was then combined with an anode porous transport layer (PTL), cathode gas diffusion layer (GDL), and gasketing to make the membrane electrode assembly (MEA). The MEA was assembled into a cell testing hardware.

The resulting thin film has high porosity and high surface area of the catalyst interface. Because the surface area of the catalyst interface is proportional to the reaction kinetics, an increased surface area is advantageous for performance of the resulting electrode assembly. The high porosity can also assist in enhancing mass transport properties of the film. Moreover, it is believed that the presence of nanobubbles in the coating composition may improve the dispersion of the ionomer within the catalyst ink, e.g., due to the electrostatic nature of the nanobubbles and their interaction with surfactants such as the ionomers used in this fabrication process.

### Example 2: Performance of the Membrane Electrode Assembly (MEA) Fabricated Using Nanobubble-Containing Catalyst Ink

This Example describes the performance of the membrane electrode assembly (MEA) prepared as described in Example 1. The MEA prepared using nanobubble-containing catalyst ink is also referred to as a nanobubble-treated catalyst layer (NB-treated CL). As a control, a MEA was prepared as described in Example 1 except that the catalyst ink was free of nanobubbles. The control MEA is referred to as the baseline CL.

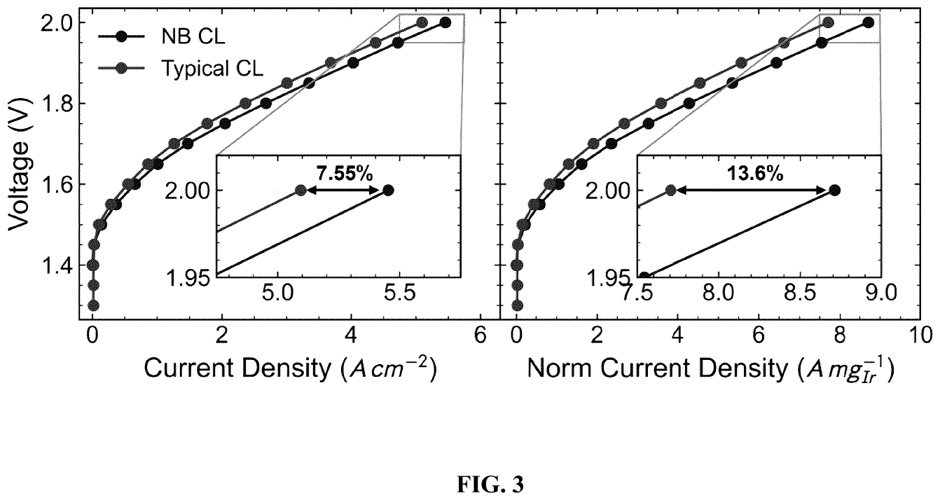

Polarization curves were collected for the NB-treated CL and the baseline CL. As shown in FIG. 3, the NB-treated CL outperformed the baseline CL despite the NB-treated CL having a lower anode catalyst content. For example, using the current density at 2V as a metric of performance comparison, the NB-treated CL outperformed the baseline CL by 7.55% when normalized by the cross-sectional geometric area and 13.6% when normalized by the total mass of the anode catalyst (FIG. 3). These results suggest that if the NB-treated CL had the same catalyst loading (loading determined as mass/area) as the baseline CL, then the overall performance improvement of the NB-treated CL would be around 13.6%.

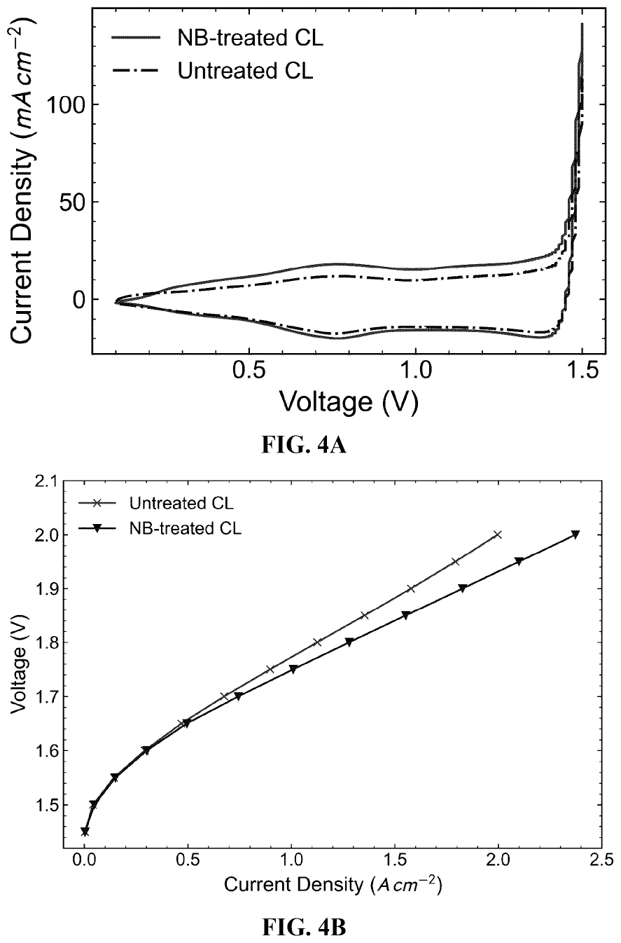

Cyclic voltammetry (CV) curves were collected for the NB-treated CL and the baseline CL. At or around 1V, the CL/membrane interface acts similarly to a pure capacitor. The current at this voltage is known as the double layer current (IDL), which is directly proportional to the electrochemical active surface area (ECSA) of a CL. As shown in FIG. 4A, the IDL for the NB-treated CL is larger than that of the baseline CL, which indicates that the ECSA of the NB-treated CL is increased compared to that of the baseline CL. As shown in FIG. 4B, the NB-treated CL produces lower voltage than the baseline CL at current densities above 0.5 A·cm⁻², which indicates that the NB-treated CL has increased mass transport compared to the baseline CL.

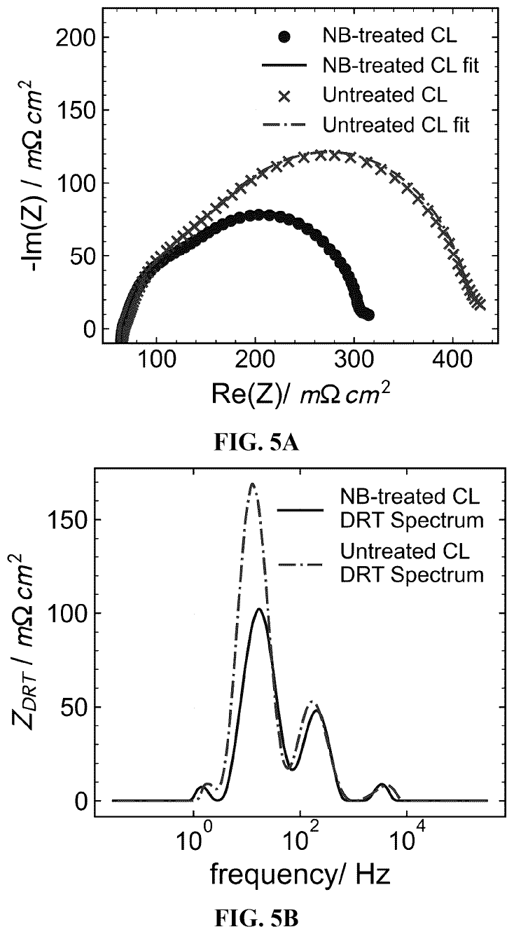

Electrochemical impedance spectroscopy (EIS) data was collected at 1.5 V for the NB-treated CL and the baseline CL. As shown in the Nyquist plot (FIG. 5A), the baseline CL incurs more electrode resistance than the NB-treated CL. A distribution of relaxation time (DRT) analysis of the EIS experimental datasets was performed to produce the line fits shown in FIG. 5A and the DRT spectra shown in FIG. 5B. The second peaks from the x-axis in FIG. 5B correspond to the resistance of the anode faradaic reaction (oxygen evolution reaction (OER)). The third peaks from the x-axis in FIG. 5B correspond to anode CL charge transfer resistance, which is dominantly due to proton transport in the ionomer phase of the CL. The second and third peak of the NB-treated CL is lower than the second and third peak of the baseline CL, which suggests that the NB-treated CL provides better reaction kinetics and charge transport characteristics than the baseline CL. This observed improvement in reaction kinetics and charge transport characteristics can be attributed to improved ionomer distribution in the NB-treated CL compared to the baseline CL.

Taken together, these results demonstrate that the NB-treated CL displayed improved performance (e.g., catalytic utilization, increased ECSA, increased mass transport, and improved ionomer distribution) compared to the baseline CL.

### Example 3: Structural Characterization of the Membrane Electrode Assembly (MEA) Fabricated Using Nanobubble-Containing Catalyst Ink

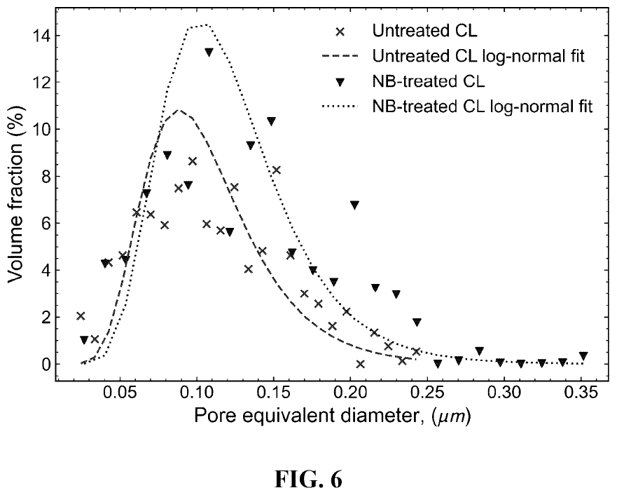

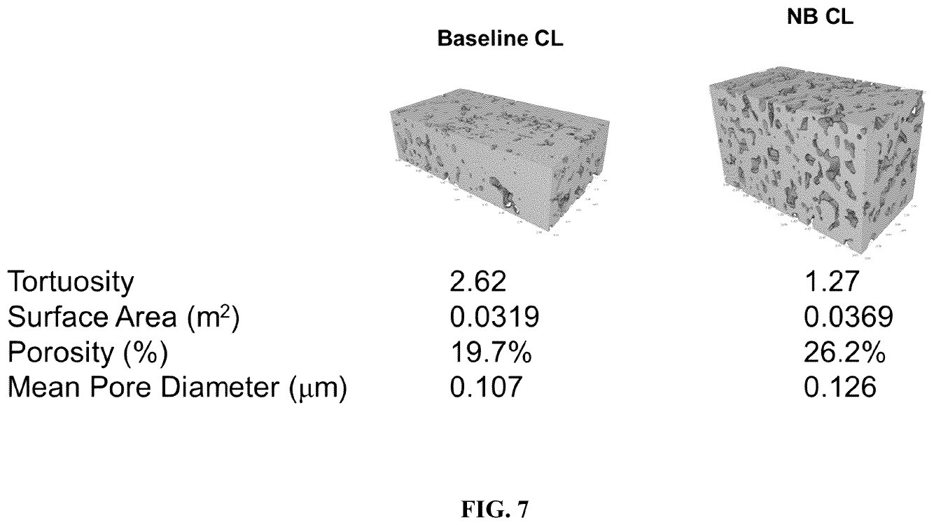

This Example describes the structural and morphological differences between the NB-treated CL and the baseline CL. Focused ion beam scanning electron microscopy (FIB-SEM) was used to image the surface and internal structure of the NB-treated CL and the baseline CL. Pore size distribution, porosity, tortuosity, and surface area were determined from the FIB-SEM data. As shown in FIG. 6, the surface area and porosity of the NB-treated CL was significantly larger than the surface area and porosity of the baseline CL. The tortuosity of the NB-treated CL was far lower than that of the baseline CL, which indicates that the NB-treated CL has enhanced mass transport properties compared to the baseline CL (FIG. 6). Additionally, as shown in FIG. 7, the log-normal distribution of pores of the NB-treated CL covered a wider range of pore sizes than those of the baseline CL, indicating a hierarchy of pore sizes, which can be better for transport.

As shown in FIG. 6, the NB-treated CL has a significantly larger number of pores around 100 nm, which is similar to the size of the nanobubbles in the solvent added to the catalyst ink used to produce the NB-treated CL. The characteristics of the nanobubbles in the solvent before the solvent was added to the catalyst ink were as follows:
Mean bubble size: 129.1 nm
Nanobubble concentration: 1.07×10⁹ mL⁻¹.

The mean bubble size was similar to the size of the mean pore diameter, which can contribute to the increase in the number of pores around 100 nm.

Taken together, the results demonstrate that there are structural and morphological differences between the NB-treated CL and the baseline CL. These structural and morphological differences include differences in pore size distribution, porosity, tortuosity, and surface area.

### Example 4: Evaluation of the Effect of Nanobubble (NB) Treatment on Ionomer Coverage on Iridium Oxide Catalyst Layer

In this Example, the effect of nanobubble (NB) treatment on the ionomer coverage of an iridium oxide catalyst layer is evaluated, which is used in water electrolysis applications. This Example employes in situ techniques to analyze ionomer coverage (θᵢₒₙ) in the catalyst layer. Both methods focus on measuring the double-layer capacitance (C_{dl}) of the electrode via cyclic voltammetry (CV) or electrochemical impedance spectroscopy (EIS).

The first technique, proposed by Iden and Ohma (see, H. Iden and A. Ohma, “An in situ technique for analyzing ionomer coverage in catalyst layers,” Journal of Electroanalytical Chemistry, vol. 693, pp. 34-41, 2013), is initially applied to a Pt/C cathode in proton exchange membrane fuel cells (PEMFC). At high relative humidity (RH), the presence of water, along with the ionomer, facilitates ion transport, increasing the interfacial area between the electron-conducting medium (catalyst) and the ion-conducting medium, which contributes to the C_{dl}. In contrast, at low RH, with minimal condensation, it is assumed that the ionomer is the sole ion-conducting medium. Therefore, the C_{dl} value under these conditions is representative of the interface between the ionomer and the catalyst. The ratio of the C_{dl} value at low RH to that at 100% RH reflects the ionomer coverage.

In this Example, a low RH of 25% is selected, which is sufficient to avoid significant capillary condensation. At 25% RH and 60° C. (the temperature used for testing), the critical pore diameter for capillary condensation is 1.24 nm, smaller than most pores in the iridium oxide catalyst layer. Thus, the ionomer coverage is calculated using the following formula:

$${θ}_{i on , IrOx} = \frac{{C}_{dl , RH 25}}{{C}_{dl , 100}}$$

However, the previous technique assumes that specific capacitance is independent of humidity, even though changes in the double-layer structure of the ionomer affect this property. To address this, Minami et al. (S. Minami, S. Kajiya, H. Yamada, K. Shinozaki, and R. Jinnouchi, “Measurement of Ionomer Coverage on Carbon and Pt in Catalyst Layer of Polymer Electrolyte Fuel Cells by Electrochemical Impedance Spectroscopy,” Electrocatalysis, vol. 14, no. 4, pp. 522-533, July 2023) proposed an alternative method using an inert fluorocarbon fluid (Fsol), which prevents ion conduction to the bare catalyst surface. Simultaneously, water vapor is introduced to the counter electrode, ensuring that water is supplied only to the ionomer in the electrode under study. Using this method, ionomer coverage is calculated as:

$${θ}_{i on , IrOx} = \frac{{C}_{dl , Fsol}}{{C}_{dl , RH 100}}$$

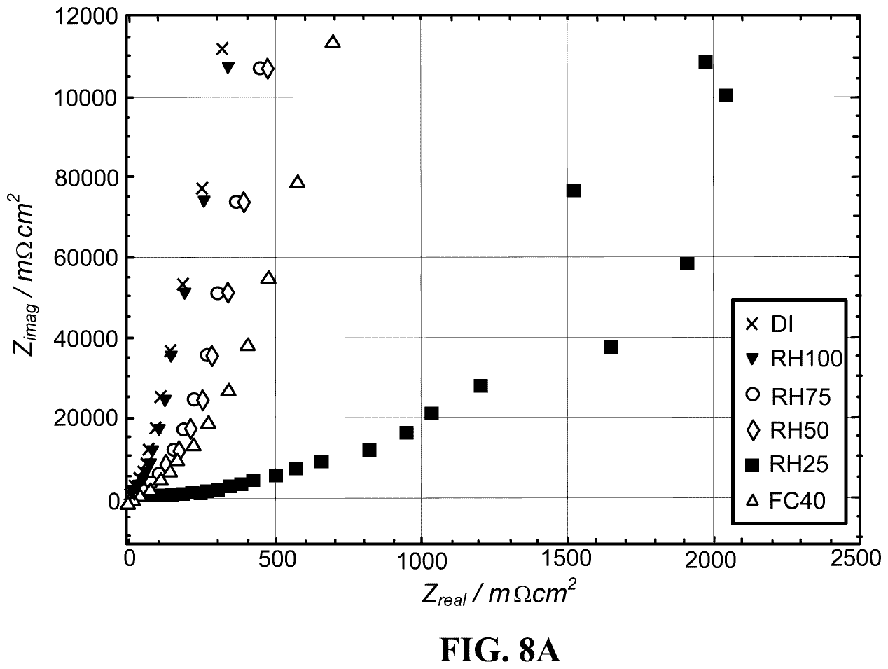

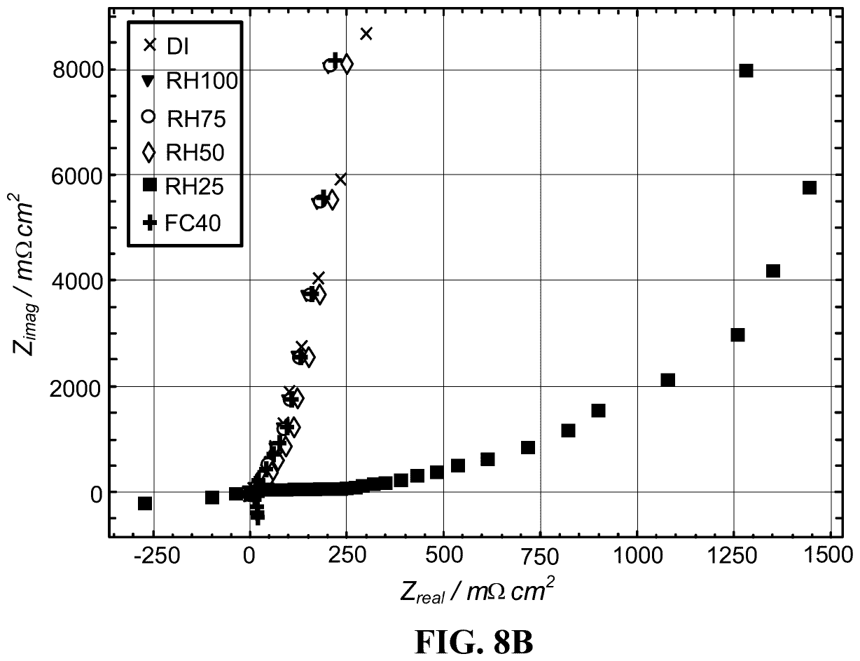

FIG. 8A and FIG. 8B present the electrochemical impedance spectroscopy (EIS) results at varying RH levels and under the fluorocarbon fluid (3M's FC40) conditions. The C_{dl} is extracted from these measurements and calculated the ionomer coverage using the formulas above.

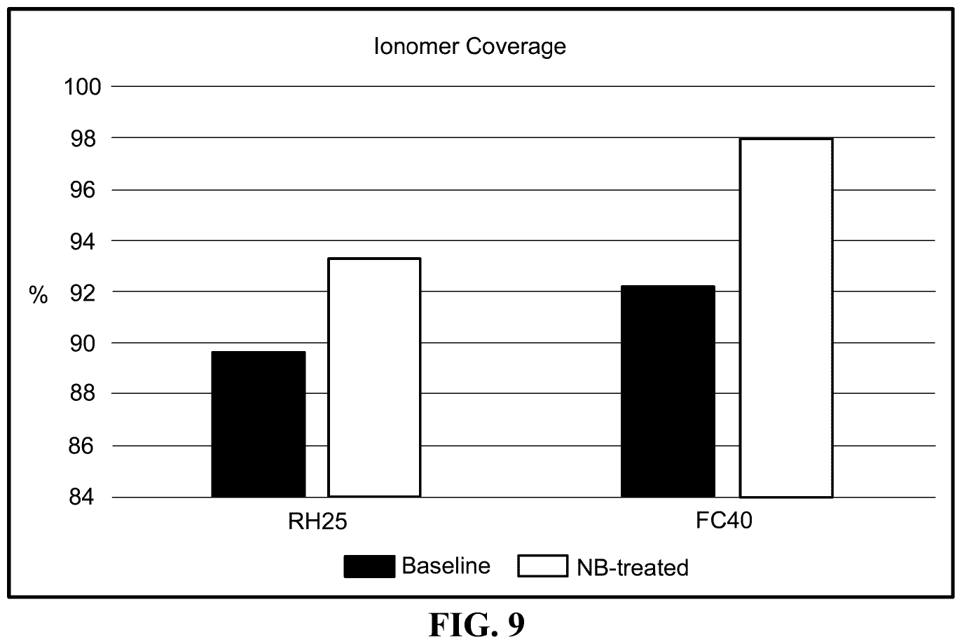

FIG. 9 shows calculated ionomer coverage values using the discussed techniques for the baseline and NB-treated CL. The results from FIG. 9 indicate that the NB-treated CL exhibits a 3.6% increase in ionomer coverage using the low RH method and a 5.8% increase using the fluorocarbon fluid method compared to the baseline. These findings suggest that nanobubble treatment can improve ionomer distribution in catalyst layers, and potentially enhance polymer distribution in other porous thin films.

### Other Embodiments

It is to be understood that while the document has been described in conjunction with the detailed description thereof, the foregoing description is intended to illustrate and not limit the scope of the document. Other aspects, advantages, and modifications are within the scope of the following claims.

What is claimed is:

1. A method of preparing an article comprising:
a) combining nanobubbles with a film-forming agent to form a coating composition; and
b) applying the coating composition to a substrate to form an article comprising a porous thin film on the substrate.

2. The method of claim 1, wherein the film-forming agent comprises a metal, a polymer, a ceramic, or a combination thereof.

3. The method of claim 2, wherein the polymer comprises an ionomer.

4. The method of claim 1, wherein the film-forming agent comprises a photoactive material, and wherein the porous thin film comprises a photoactive layer.

5. The method of claim 4, comprising:
applying a semiconductor coating composition to the substrate to form a semiconducting layer on the substrate, the semiconductor coating composition comprising nanobubbles, a semiconducting material, and a liquid carrier; and
wherein applying the coating composition to the substrate comprises applying the coating composition to the semiconducting layer to form the photoactive layer on the semiconducting layer.

6. The method of claim 4, wherein the substrate comprises a first electrode, and comprising disposing a second electrode onto the photovoltaic layer to form a photovoltaic cell.

7. The method of claim 4, wherein the photoactive material comprises an organic material, an organometallic material, a metal oxide, a perovskite, a quantum dot, a chalcogenide, or a combination of any of these.

8. The method of claim 1, wherein the film-forming agent comprises a semiconducting material, and wherein the porous thin film comprises a semiconducting layer.

9. The method of claim 8, wherein applying the coating composition to a substrate comprises applying the coating composition to an electrode.

10. The method of claim 8, wherein applying the coating composition to a substrate comprises applying the coating composition to a photovoltaic layer.

11. The method of claim 1, comprising:
combining nanobubbles, the film-forming agent, and a liquid carrier to form the coating composition; and
wherein applying the coating composition to the substrate comprises removing the liquid carrier from the coated substrate to form the article comprising the porous thin film.

12. The method of claim 11, wherein the liquid carrier comprises water.

13. The method of claim 11, wherein the liquid carrier comprises an organic solvent.

14. The method of claim 1, wherein the coating composition comprises nanobubbles, catalyst nanoparticles, and the film-forming agent.

15. The method of claim 14, wherein the catalyst nanoparticles comprise iridium oxide nanoparticles.

16. The method of claim 14, wherein the catalyst nanoparticles and film-forming agent are present in an amount ranging from 0.1-80 wt. % based on the weight of the coating composition.

17. The method of claim 14, wherein the coating composition comprises nanobubbles, catalyst nanoparticles, a liquid carrier, and the film-forming agent, wherein the film-forming agent comprises an ionomer, and
wherein the article comprises an electrode.

18. The method of claim 1, wherein the coating composition comprises nanobubbles having a mean bubble size no greater than 250 nm.

19. The method of claim 1, wherein the article comprises an electrode.

20. The method of claim 19, comprising positioning the electrode between an anode porous transport layer and a cathode gas diffusion layer to form a membrane electrode assembly.

21. The method of claim 1, wherein the article comprises a membrane.

22. The method of claim 1, wherein the article comprises a photovoltaic cell.

23. A method of preparing an electrode comprising:
a) combining nanobubbles with catalyst nanoparticles, a liquid carrier, and a polymer to form a coating composition;
b) applying the coating composition to a substrate to form a coated substrate; and
c) removing the liquid carrier from the coated substrate to form an electrode comprising a porous thin film on the substrate.

24. The method of claim 23, wherein the polymer comprises an ionomer.

25. A nanobubble-containing catalyst ink composition comprising catalyst nanoparticles, an ionomer, and nanobubbles.
